(19) United States
(12) Patent Application Publication
(10) Pub. No.: US 2008/0310492 A1
(43) Pub. Date: Dec. 18, 2008

(54) Parameter Adjustment Device and Parameter Adjustment Method

(75) Inventors: Yuji Kasai, Tokyo (JP); Masatoshi Sato, Tokyo (JP); Takashi Kamata, Tokyo (JP)

Correspondence Address: KANESAKA BERNER AND PARTNERS LLP, 1700 DIAGONAL RD, SUITE 310, ALEXANDRIA, VA, 22314-2848, US

(73) Assignees: Evolvable Systems Research Institute Inc., Tokyo (JP); The Tokyo Electoric Power Company Incorporated, Tokyo (JP)

(21) Appl. No.: 11/630,647

(22) PCT Filed: Jun. 22, 2005
(86) PCT No.: PCT/JP2005/011441

§ 371 Date: Dec. 26, 2006

(30) Foreign Application Priority Data
Jun. 25, 2004 (JP) 2004-188740
Jun. 25, 2004 (JP) 2004-188908

(51) Int. Cl. H03K 5/159

(52) U.S. Cl. 375/232

(57) ABSTRACT

Transmission equipment that can be used up to a high frequency and simplifies a circuit design includes a THP preceding means on a transmitting side, and an equalizer means, wherein analog processing is carried out on a receiving side. Compensation of the frequency characteristic of a transmission channel is divided into the THP preceding means on the transmitting side and the equalizer means, so that due to compensation by the equalizer circuit, the absolute value of a THP coefficient becomes small, and a DAC with lower resolution, wherein stability of a loop of the THP increases, can be used. Detailed adjustment for adapting to the characteristic of a transmission channel is carried out by the THP, so that the equalizer circuit is only required to roughly compensate, and is not required to adjust. As a result, the equalizer circuit can be of a simple design.

### FIELD OF THE INVENTION

The present invention relates to a parameter adjustment device and parameter adjustment method, especially, transmission equipment and a transmission method which can be used at a high frequency and which has a simple circuit design.

### BACKGROUND OF THE ART

Conventionally, a Pulse Amplitude Modulation (PAM) signal system is used for high-speed digital data transmission equipment, and in order to compensate the frequency characteristic of the transmission channel, adoption of an equalizer circuit or a pre-emphasis circuit and so on is proposed. In the following Japanese Patent Publication 1, an equalizer circuit with a transversal-filter type able to carry out digital processing and analog processing is disclosed.

However, as signal transmission speeds rise, high-pass attenuation enormously increases, so that the equalizer circuit alone had a limit. Also, regarding the pre-emphasis circuit system, since the level of the high-pass component in the transmitting end increases, if a LAN cable wherein multiple twisted pair cables are housed is used, crosstalk inevitably increases.

Consequently, a THP (Tomlinson Harashima Precoding) system has recently drawn attention. This THP system is a system wherein the pre-emphasis system is improved; and a modulo arithmetic circuit is inserted in the way of the pre-emphasis circuit with an FIR filter which has an artificial transmission channel, so that amplitude of an output signal can be controlled within a predetermined range. In the following nonpatent Publication 1, a waveform adjustment technique with a THP system is disclosed.

Japanese Patent Publication 1: Japanese Patent Publication No. H8-46553

Japanese Nonpatent Publication 1: “Matched-Transmission Technique for Channels With Intersymbol Interference” IEEE TRANSACTIONS ON COMMUNICATIONS, VOL.COM-20, NO. 4 AUGUST 1972 p.p. 774˜780.

### DISCLOSURE OF INVENTION

### Problems to be Resolved by the Invention

In the above-mentioned conventional THP system, the signal level in the transmitting end is controlled within the predetermined width. However, in the signal received through the transmission channel, although the absolute value is attenuated, an available value of a signal value is diffused, and as shown in FIG. 6(b), inevitably, spreads several times (for example, 7 times) more than the signal width on the transmitting side. Therefore, when this signal is converted to a digital signal by an analog to digital (AD) converter, a portion of the width of the spread signal is required to be converted by predetermined resolution, so that a high-accuracy AD converter is required. Also, if the transmission channel is attempted to be compensated only by the Tomlinson Harashima Precoding(THP), the THP processing inevitably becomes unstable.

### Means of Solving the Problems

The present invention is made in order to solve the above-mentioned problems, and the main feature of the transmission equipment of the invention is that, a THP preceding means is provided on the transmitting side, and an equalizer means wherein analog processing is carried out is provided on the receiving side.

### Effect of the Invention

According to the above-mentioned structure, since compensation of the frequency characteristic of the transmission channel is divided into a THP precoding means on the transmitting side and an equalizer means wherein analog processing is carried out on the receiving side, the transmission equipment of the present invention has the following effect.

(1) Due to compensation by an equalizer circuit, the absolute value of the coefficient (from al to an, in FIG. 2B) of THP becomes small, and the stability of the loop of the THP increases. More specifically, the absolute value of the solution of the characteristic equation by the coefficient (from al to an) of the THP becomes small, and operation of the THP becomes very stable.

(2) As shown in FIG. 6(a), since the above-mentioned spread of the received signal is compressed, for example, into less than half, a digital analog converter (DAC) with lower resolution can be used.

(3) Detailed adjustment for adapting to the characteristic of the transmission channel is carried out by the THP, so that the equalizer circuit is only required to perform rough compensation, and not required to perform adjustment. As a result, the design for the equalizer circuit becomes simpler.

(4) The number of step of the THP precoder can be reduced.

(5) In the THP system, a DC component called DC wander is generated on the receiving side; however, a direct current component can be eliminated by the equalizer, and the DC wander can be reduced.

### BRIEF DESCRIPTION OF THE DRAWING

FIG. 1 is a block diagram showing the whole structure of the transmission equipment of the present invention.

FIGS. 2(a) 2(b) are block diagrams showing the structure of a THP precoder 12.

FIG. 3 is a block diagram showing the structure of an equalizer circuit.

FIG. 4 is an explanatory drawing showing an example of the operation of a code converter 11.

FIG. 5 is a graph showing input-output characteristics of a modulo computing unit 41.

FIGS. 6A and 6B are an explanatory drawings showing the difference in the spread of a received signal.

FIG. 7 is a block diagram showing a modified example of the first embodiment.

FIG. 8 is a block diagram showing the structure of an embodiment 1 of the equalizer circuit of the present invention.

FIGS. 9(a), 9(b) are a functional block diagram and a circuit diagram showing the structure of an adder circuit.

FIG. 10 is a circuit diagram showing the circuit structure of the embodiment 1 of the equalizer circuit.

FIG. 11 is a circuit diagram showing a structural example of the adder circuit in an embodiment 2.

FIG. 12 is a circuit diagram showing the circuit structure of the embodiment 2 of the equalizer circuit.

FIG. 13 is a block diagram showing the circuit structure of an embodiment 3 of the equalizer circuit.

FIG. 14 is a block diagram showing the structure of a hybrid circuit for a twisted pair wire.

FIG. 15 is a circuit diagram showing the circuit structure of the embodiment 1 of the hybrid circuit.

FIGS. 16(a) and 16(b) include plan views and diagrams of a connection showing the structure of a transformers.

FIG. 17 is a block diagram showing the structure of a coaxial hybrid circuit.

FIG. 18 is a block diagram showing a modified example of the circuit in FIG. 17,

FIG. 19 is a circuit diagram showing the circuit structure of the embodiment 2 of the hybrid circuit.

FIG. 20 is a circuit diagram showing a modified example of a circuit example of the embodiment 2 of the hybrid circuit.

FIG. 21 is a block diagram showing the structure of an SS encoder of the present invention.

FIG. 22 is a block diagram showing the structure of an SS decoder of the present invention.

FIG. 23 is a block diagram showing the structure of an SS THP encoder.

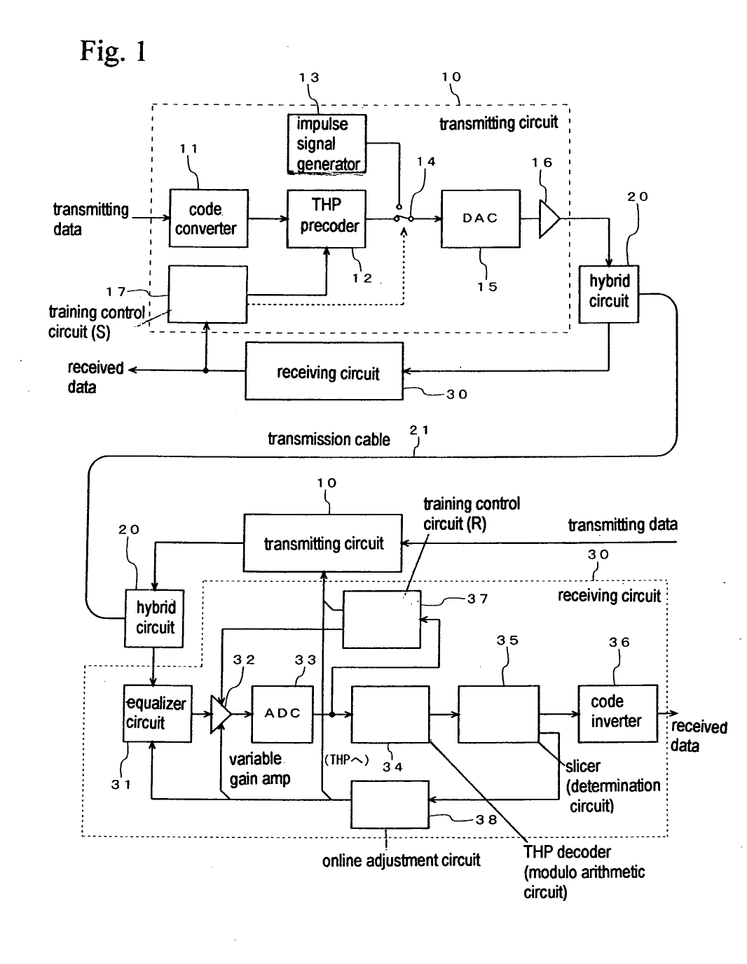

### EXPLANATION OF SYMBOLS IN FIG. 1

10 Transmitting circuit
11 Code converter
12 THP precoder
13 Impulse signal generator
14 Switch
15 D/A converter
16 Amp
17 Training control circuit (S)
20 Hybrid circuit
21 Transmission cable
30 Receiving circuit
31 Equalizer circuit
32 Variable gain amp
33 A/D converter
34 THP decoder
35 Slicer (Determination circuit)
36 Code inverse transform circuit
37 Training control circuit (R)
38 Online adjustment circuit

### DETAILED DESCRIPTION OF PREFERRED EMBODIMENTS

Transmission equipment of the present invention is developed for being used for very-high-speed digital data transmission equipment (LAN) with more than a number of Gbps typified by a balance cable or coaxial cable using a twisted pair cable. However, the transmission equipment of the present invention is not limited to the embodiment described hereinabove, and can be applied to the transmission equipment of an optional signal. Hereinafter, an embodiment will be explained.

### EMBODIMENT 1

FIG. 1 is a block diagram showing the whole structure of transmission equipment of the present invention. This embodiment comprises full-duplex data transceiving equipment which is connected to both ends of a transmission cable 21 and has the same structure. A transmitting circuit 10 comprises a code converter 11, THP precoder 12, impulse signal generator 13, DAC (D/A converter) 15, amp 16, and training control circuit (S) 17.

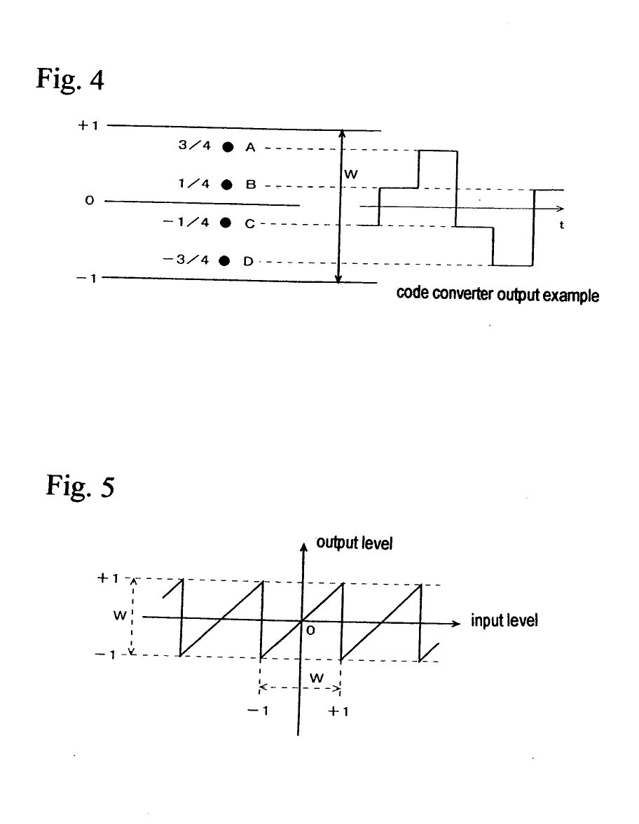

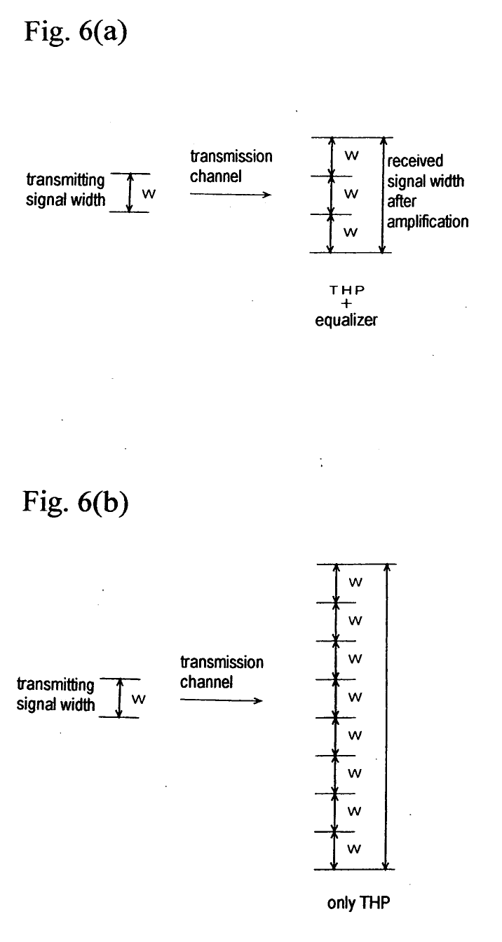

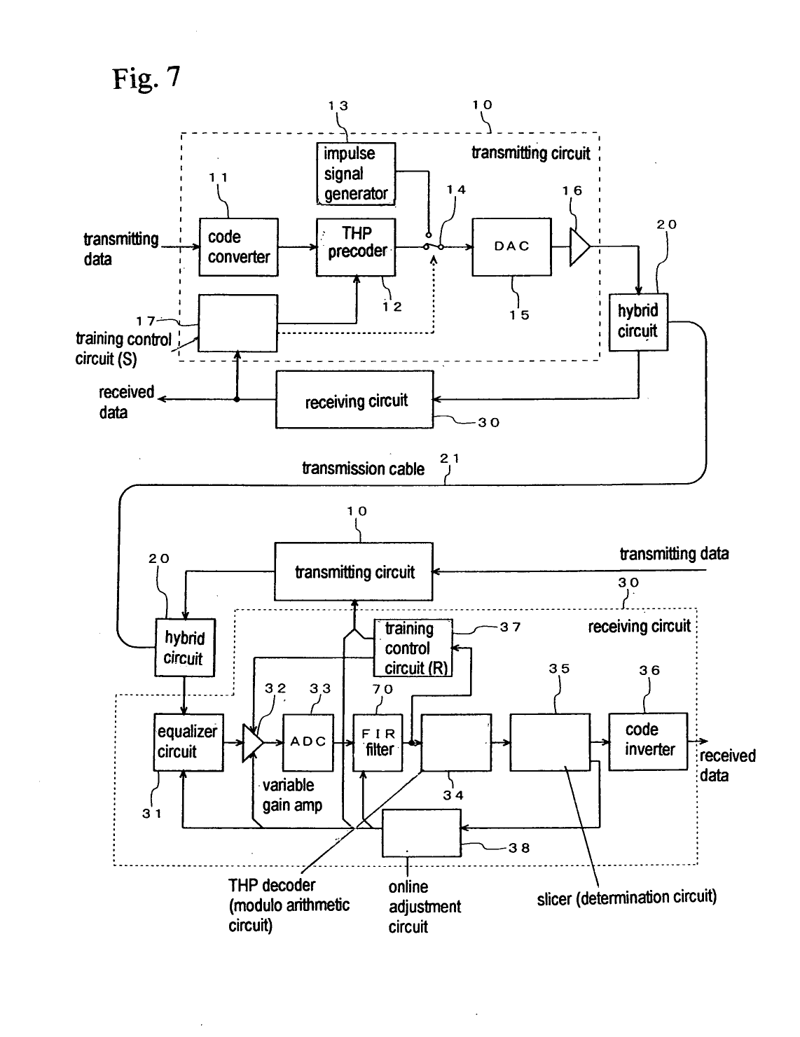

The code converter 11 divides transmitting data with respect to each predetermined bit, and outputs one of multiple signal levels (voltage level) in response to a value of its bit sequence. FIG. 4 is an explanatory drawing showing an example of operation of the code converter 11. This example converts 2 bits to 4 values (A˜D). The following modulo arithmetic processing width W is, for example, −1˜+1, and 4 values, may for example be A=¾, B=¼, C=−¼, D=−¾. The number of the signal level is optional. An interval between the boundary level (for example, +1) of the modulo arithmetic processing width W and the signal value (for example, ¾) of the end only requires more than ½ of a signal interval (=½). The output signal of the code converter 11 is graphed in the right side of FIG. 4.

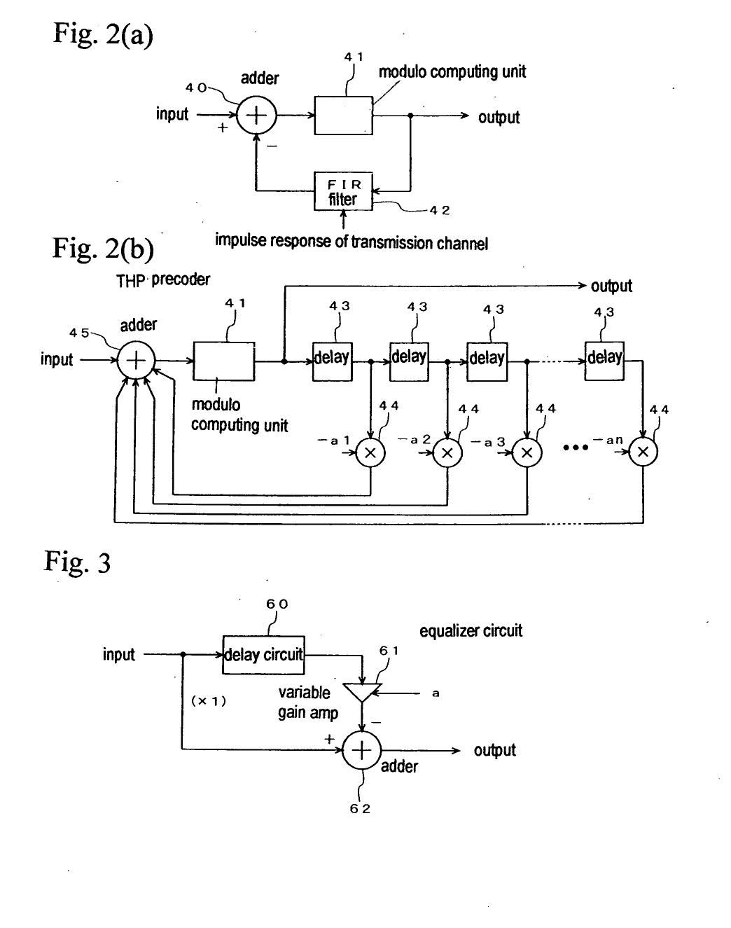

FIGS. 2(a) and 2(b) are block diagrams showing the structure of the THP precoder 12. FIG. 2(a) is a functional block diagram. The THP precoder 12 comprises an adder 40, modulo computing unit 41, and Finite Impulse Response (FIR) filter 42. In the FIR filter 42, a coefficient of the impulse response of a transmission channel, including an equalizer circuit is set by training processing. The FIR filter 42 inputs the output of the modulo computing unit 41, processes it, and outputs to the adder 40. The adder 40 subtracts the output of the FIR filter 42 from the input signal and outputs that result.

FIG. 5 is a graph showing input-output characteristics of the modulo computing unit 41. The modulo computing unit 41 functions in such a way that the output signal is fitted into the predetermined width W. More specifically, if the input signal runs beyond the range of the width W, the input signal is fitted into the width W by subtracting the amount wherein the width W is multiplied by an integral number. As shown in the embodiment, if the width W is −1˜+1, a modulo arithmetic result can be obtained by allowing the upper-portion bit of the input signal to be 0.

FIG. 2(b) is a drawing showing a more detailed circuit structure. An adder 45 combines both functions of the adder 40 and the FIR filter 42. A delay circuit 43, which is a component part of the FIR filter is a shift register for allowing the signal to delay only for one signal section (for one clock). A multiplier 44 multiplies the coefficient (−a1˜−an) of the impulse response of the transmission channel. The number of steps of the FIR filter is, for example, 16˜64. The output of the THP precoder 12 is converted to an analog signal by the DAC 15, and transmitted through the amp 16 and a hybrid circuit 20, as illustrated in FIG. 1.

The training control circuit (S) 17 generates an impulse response coefficient which is set in the THP precoder 12. For example, when the power of the equipment is turned on, the training control circuit (S) 17 switches a switch 14 to the impulse signal generator; sends the impulse signal to the transmission channel; receives impulse response coefficient data which was sent back from the circuit on the receiving side; and sets it in the THP precoder 12. Also, even during the signal transmission, based on an evaluation result of the signal on the receiving circuit side, the coefficient can be adjusted based on, for example, genetic algorithm.

Next, the receiving circuit will be explained. A receiving circuit 30 comprises an equalizer circuit 31, variable gain amp 32, ADC (A/D converter) 33, THP decoder 34, slicer (determination circuit) 35, code inverse transform circuit 36, training control circuit (R) 37, and online adjustment circuit 38.

FIG. 3 is a block diagram showing the structure of the equalizer circuit. The equalizer circuit 31 is the heretofore known FIR-type analog filter circuit. A delay circuit 60 is the circuit which allows the signal to delay for one signal section, and can adopt a delay line using the coaxial cable and so on, or an all-pass filter circuit. A variable gain amp 61 multiplies a coefficient “a” of the filter by the output signal of the delay circuit 60 by controlling gain based on the coefficient “a” of the filter. An adder 62 subtracts the output signal of the variable gain amp 61 from the input signal.

The structure of FIG. 3 can adjust the characteristic; however, the coefficient may be fixed (for example, 1). In this case, since the variable gain amp 61 is not required, the design of the equalizer circuit becomes simpler, and the noise from the amp disappears.

The variable gain amp 32 in FIG. 1 amplifies the received signal so that the output signal level of the analog to digital converter (ADC) 33 becomes the same signal level as the input signal of the DAC 15 of the transmitting circuit. The ADC 33 converts the signal from analog to digital. The THP decoder 34 is a modulo arithmetic circuit with the same characteristics as the modulo computing unit 41 inside the THP precoder 12 shown in FIG. 5.

The slicer (determination circuit) 35 is the circuit which determines within which area the signal with multiple values exists. In the example in FIG. 4, if the input signal level is below −½, the slicer 35 outputs [0001]; if the input signal level is over −½ and below 0, the slicer 35 outputs [0011]; if the input signal level is over 0 and below ½, the slicer 35 outputs [0111]; and if the input signal level is over ½, the slicer 35 outputs [1111]. The code inverter 36 inversely converts the output of the above-mentioned slicer to the original bit information (for example, 2 bits of information).

The training control circuit (R) 37 cooperates with the training control circuit (S) 17 of the transmitting circuit, receives an impulse response signal from the output of the ADC 33, and sends back to the training control circuit 17 of the transmitting circuit 10 on the other side through the transmitting circuit 10. Also, by using a training signal, gain of the variable gain amp 32 is adjusted.

The online adjustment circuit 38 includes a CPU, and obtains more detailed signal evaluation information, for example, to which side and how far the signal is run off from the center level of the signal arrangement by the slicer 35. In order to improve the evaluation value, an adjustable coefficient such as the equalizer circuit 31, variable gain amp 32, THP precoder 12 on the transmitting side and so on are simultaneously adjusted based on, for example, the genetic algorithm.

FIG. 7 is a block diagram showing a modified example of the first embodiment. This embodiment is the embodiment wherein an FIR filter 70 is added to the structure of the first embodiment. In the case of the THP system, modulo arithmetic is carried out on the receiving side; however, in this case, if an initial rise of the received signal is not steep, an error rate inevitably becomes large, so that the signal level just before the peak of the signal is preferably as close to 0 as possible.

However, there may be a case wherein the combination of the THP system of the first embodiment and the equalizer circuit cannot completely eliminate “slowness” of the initial rise of the received signal. Consequently, by adding the FIR filter with a high-frequency pass characteristic which eliminates the dullness of the initial rise in the back of the ADC 33, the error rate declines by eliminating the dullness of the initial rise of a signal waveform. Incidentally, the coefficient of the FIR filter 70 may also be adjusted by the online adjustment circuit 38.

### Equalizer Circuit

Next, details of the equalizer circuit will be explained. As mentioned above, the equalizer circuit can be obtained by using a transversal filter. As the result of an experiment, the present inventor found that the number of delay steps of the transversal filter to function as the equalizer circuit is one step, as a fundamental form, and according to a necessary characteristic, a plurality of fundamental forms of one step may be cascaded. The inventor also found that the filter, wherein a transfer function F is represented by the following numerical formula 1, may be obtained as the fundamental form of the transversal filter.

F=G(1−kẐ−1) . . . Numerical formula 1

However, G=1/(1−k) or a value proportional to this value. Also, the symbol indicates that the next numerical value is an exponent. In the embodiment, the output signal of the equalizer circuit is estimated by heretofore known means, and the equalizer circuit is adjusted by gain adjustment by the variable gain amp, and the reference alphabet G is set in an optimal value by this adjustment.

The reference alphabet k represents a coefficient which changes by the length of the cable and so on, and depending on the length of the cable, the coefficient k is required to be adjusted within approximately 0.9˜0.95. In the case wherein this transfer characteristic is obtained, when the variable gain amp is used in order to multiply the delayed signal by −k, the longer the length of the cable, the more the signal attenuates and the more the value of k approaches 1. As a result, a low-noise amp, which can accurately control gain and has a wide dynamic range, is required for the variable gain amp. However, in a frequency over a few hundreds MHz, this kind of variable gain amp is very difficult to obtain or produce. Consequently, the present inventor invented a circuit, shown as follows, which obtains the above-mentioned characteristic.

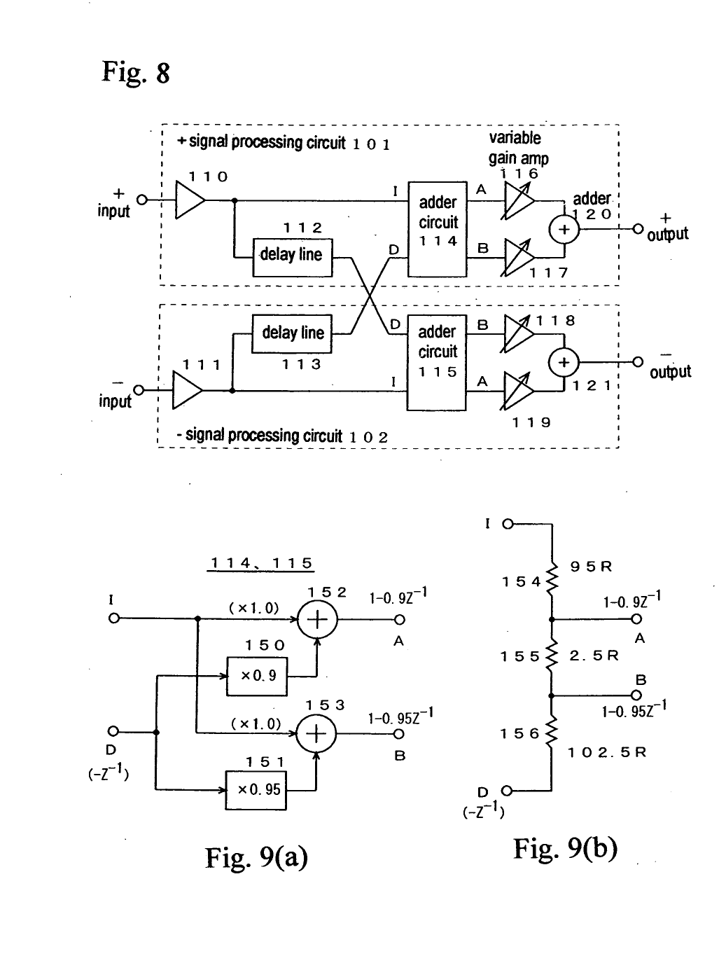

FIG. 8 is a block diagram showing the structure of the embodiment 1 of the equalizer circuit of the present invention. In the circuit in FIG. 8, a + side signal processing circuit 101 and − side signal processing circuit 102 have the same structure. Therefore, only the upper side circuit 101 will be explained. In the upper side (lower side) of the circuit 101, + output signal (− output signal) of the differential output signal of the hybrid circuit 20 is input. The input signal is input into an amp 110 and amplified by a predetermined gain.

An output signal (I) of the amp 110 is input into an adder circuit 114 and delay line 112. The delay line 112 is a delay means allowing a differential signal to delay, and a coaxial cable with a predetermined length can be used. An output (D) of the delay line 112 is output into an adder circuit 115 of the other signal processing circuit 102. The adder circuit 114 is an adder means that inputs the output signal (I) of the amp 110, which is a plus side signal of the differential signal, and the output signal (D) of a delay line 113, which is the delay means on the minus side. The adder circuit outputs multiple adder signals wherein two signals are added in varying proportions respectively.

FIGS. 9(a) and 9(b) include functional block diagram and a circuit diagram showing the structure of the adder circuit. FIG. 9(a) is a functional block diagram showing the function of the adder circuit 114. An input signal I, which is the output signal of the amp 110 (111), is directly (×1.0) input into two adders 152, 153 respectively. On the other hand, an output signal (D) of the delay line 113 (112) is input into two multipliers (attenuators) 150, 151, and signals which are 0.9 times and 0.95 times full scale are output from respective multipliers (attenuators) 150, 151. Two adders 152, 153 add outputs of the respective multipliers 150, 151 to the signal I, and output them. As a result, as an output of the adder circuit 114, the output signal of A=(1−0.9Ẑ−1) and B=(1−0.95Ẑ−1) can be obtained.

FIG. 9(b) is a circuit diagram showing a structural example of the adder circuit 114. The adder circuit 114 of the present invention can be obtained by a series circuit of multiple (three) resistances as shown in the figure. When the input impedance of variable gain amps 116 and 117, which are connected to an output terminal A and an output terminal B, is large enough, output signals equivalent to A=[(1−0.9Ẑ−1)×g1] and B=[(1−0.95Ẑ−1)×g2] are obtained in the two output terminals that are both ends of a resistance 155, by making the ratio of the resistance values of three resistances 154, 155, 156, for example, 95:2.5:102.5.

The ratio of the resistance values are not limited to the above-mentioned example, but can be arbitrarily set in a range able to cover the adjustable range of the equalizer circuit. Also, references g1, g2 represent fixity coefficients wherein g1≠g2, so that the levels of the two output signals of this circuit are not strictly consistent. However, since respective signal levels are adjusted by the variable gain amps 16, 17 on the back step, there is no problem.

Even in the case wherein the input impedance of the variable gain amps 116, 117, which are connected to the output terminals A, B, is not large enough, the resistance value of the resistance 154: resistance 155: resistance 156 can be designed by the heretofore known design method, and the output signals equivalent to A=[(1−0.9Ẑ−1)×g1] and B=[(1−0.95Ẑ−1)×g2] are obtained in the output terminals A, B.

In the variable gain amps 116, 117 which are variable gain amplification means, the training control circuit (R) 37 or online adjustment circuit 38 adjusts the equalizer characteristic (relative gain of each variable gain amp) so that, for example, the error rate of the received signal becomes the minimum by the heretofore known method. For example, if the gains of the variable gain amps 116, 119 are the maximum, and the gains of the variable gain amps 117, 118 are the minimum (0), the characteristic of the filter becomes (1−0.9Ẑ−1). However, if all the gains of the variable gain amps 116˜119 are the same (maximum), the characteristic of the filter becomes roughly (1−0.925Ẑ−1). One of the variable gain amps 16, 17 may be fixed gain and only the other may be adjusted. An adder 120, which is an output synthetic means adds, synthesizes, and outputs the output signals of two variable gain amps 116, 117.

In the case wherein a signal of a single end is processed, by using only the + signal processing circuit 1 (except for the delay line 112), the amp 111, and the delay line 113, the input signal of the single end may be converted to the differential signal by using a differential amplifier or common-mode choke transformer and so on, and may be input into a + input and − input.

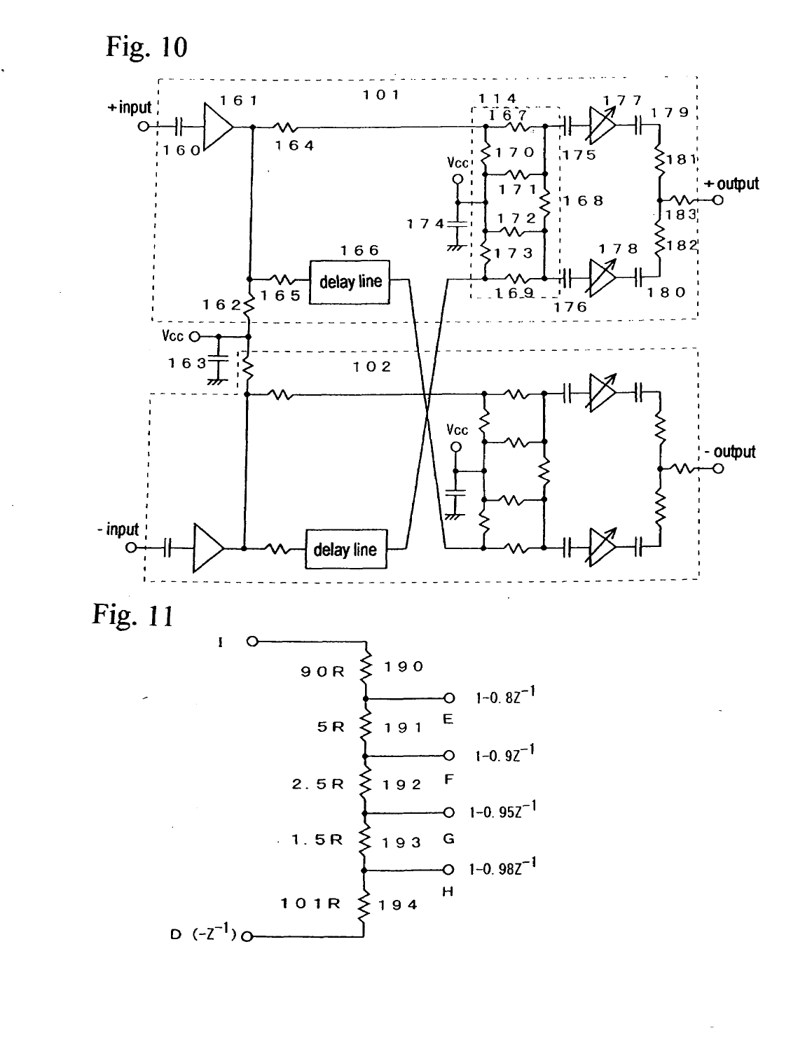

FIG. 10 is a circuit diagram showing an exemplary circuit of the embodiment 1 of the equalizer circuit. Since the upper side and lower side of the circuit are the same, only the upper side of a circuit 101 will be explained. A + input signal is input into an amp 161 through a direct-current cut condenser 160. As the amp 161, for example, a monolithic amp IC, ERA-4 by Mini-Circuits (registered trademark) can be used. Since this IC has 50 Ω of output impedance and supplies power through the output end, the power is supplied through resistances equivalent to resistances 167˜173 of the adder circuit 114; resistances 164, 165; a delay line 166; and resistances 167˜173 of the adder circuit 114 of the − signal processing circuit 102 as well as load resistance 162 (for example, 330 Ω).

The output of the amp 161 is input into a resistance network comprising the delay line 166 and adder circuit 114 through the resistances 164, 165 (for example, 43 Ω) for signal distribution and impedance matching. For the delay line 166, for example, a coaxial cable with characteristic impedance 75 Ω of a predetermined length can be used. Among the resistances in the resistance network, resistances corresponding to the resistances 154, 155, 156 in FIG. 9(b) are the resistances 167, 168, 169. The other resistances 170˜173 are resistances for impedance matching or for supply power, and not for adding processing.

One example of resistance value for each resistance comprising the resistance network will be shown hereinafter. Resistance 167=138 Ω, resistance 168=2.2 Ω, resistance 169=150 Ω, resistance 170=150 Ω, resistance 171=300 Ω, resistance 172=300 Ω, and resistance 173=150 Ω. In this case, the value of the above-mentioned reference alphabet k can be adjusted in the range of 0.9˜0.95. Condensers 163, 174, 175, 176, 179, 180 are direct-current cut condensers, and equivalent to a condenser whose both ends are shorted for alternating current.

Two variable gain amps 177, 178 amplify a signal by gain which is externally set. As the variable gain amp 177, for example, an AD8370 by ANALOG DEVICES (registered trademark) can be used. This IC can digitally control gain externally. Also, a μPC2712TB by NEC (registered trademark) can be used. Since this IC can adjust the gain by changing the power supply voltage, a power supply circuit able to control power voltage is required in order to adjust the gain.

Three resistances 181˜183, comprising the adder 20, add, synthesize, and output the output signals of two variable gain amps 177, 178.

According to the above-mentioned structure, an equalizer circuit operable up to very high frequency can be obtained only by a currently available or manufacturable element. Also, except for the delay lines, the structure can be an IC.

### EMBODIMENT 2 OF EQUALIZER CIRCUIT

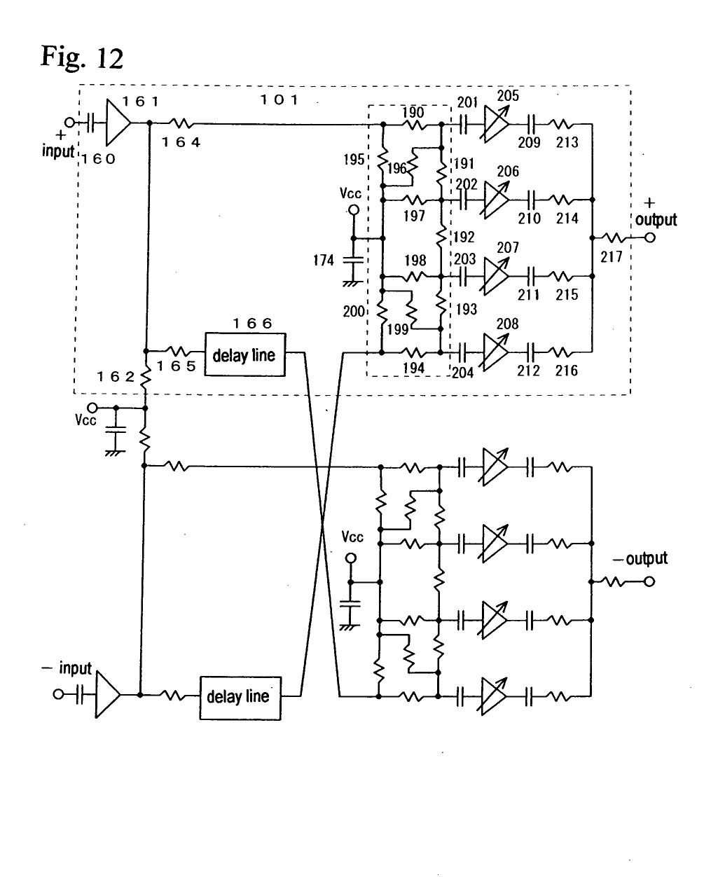

FIG. 12 is a circuit diagram showing the circuit structure of an embodiment 2 of the equalizer circuit of the invention. The embodiment 2 is an example of the equalizer circuit of the invention in the case wherein the number of output signals from the adder circuit is four. In the circuit structure of the embodiment 1, if a wide adjustable range associated with the length of the cable is attempted to be covered, the accuracy of equalization especially in the area wherein the above-mentioned coefficient K is close to 1, inevitably deteriorates. Consequently, in the embodiment 2, by subdividing the area wherein the coefficient K is close to 1; providing multiple outputs corresponding to respective areas; and controlling gains of the variable gain amps, desired characteristics are synthesized.

The difference between the circuit diagram shown in FIG. 12 and the circuit of the embodiment 1 shown in FIG. 10 is the rest of the structure of the resistance network comprising the adder circuit 114; four different output signals are output through the resistance network; and four variable gain amps (205˜208) are also provided.

FIG. 11 is a circuit diagram showing a structural example of the adder circuit in the embodiment 2. The circuit of the embodiment 2 is obtained by a series circuit of five resistances as shown in the figure. These resistances are equivalent to resistances 190˜194 in FIG. 12, and the rest of resistances 195˜200 is resistances for the impedance matching or power supply, and not for the adding processing.

When the input impedance of the variable gain amps which are connected to output terminals E˜H is large enough, output signals equivalent to E=[(1−0.8Ẑ−1)×g3], F=[(1−0.9Ẑ−1)×g4], G=[(1−0.95Ẑ−1)×g5], and H=[(1−0.98Ẑ−1)×g6] are obtained in the four output terminals by making the ratio of resistance values of the above-mentioned five resistances 190:191:192:193:194, for example, 90:5:2.5:1.5:101. Incidentally, the references g3˜g6 represent fixity coefficients.

Even if the input impedance of the variable gain amps is not large enough, the resistance values of the resistances 190:191:192:193:194 can be designed by the heretofore known design method, and the output signals equivalent to E=[(1−0.8Ẑ−1)×g3], F=[(1−0.9Ẑ−1)×g4], G=[(1−0.95Ẑ−1)×g5], and H=[(1−0.98Ẑ−1)×g6] are obtained in four output terminals.

An example of the resistance value of each resistance comprising the resistance network in FIG. 12 is shown 20 hereinafter. Resistance 190=134Ω, resistance 191=2.4 Ω, resistance 192=1 Ω, resistance 193=0.68 Ω, resistance 194=150 Ω, resistance 195=150 Ω, resistance 196=300 Ω, resistance 197=300 Ω, resistance 198=300 Ω, resistance 199=300Ω, and resistance 200=150 Ω.

Four variable gain amps 205˜208 are controlled in such a way that at most, only two amps operate at the same time.

More specifically, when the characteristic of the filter is preferred to be approximately (1−0.97Ẑ−1), the gain of the variable gain amp 207 may be set at the medium degree, the gain of the variable gain amp 208 may be set at the highest; and the gains of the variable gain amps 205, 206 may be the least (0).

According to the above-mentioned structure, more high-accuracy equalization may be possible over a wide adjustable range.

### EMBODIMENT 3 OF EQUALIZER CIRCUIT

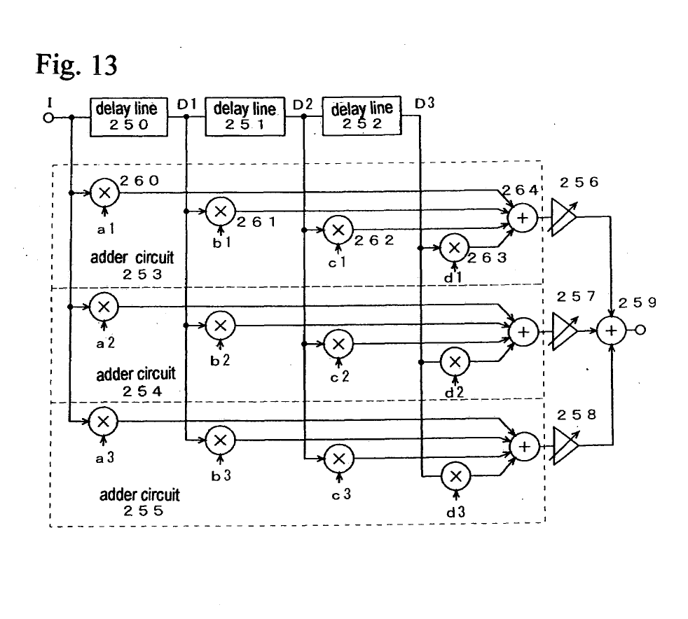

FIG. 13 is a block diagram showing the circuit structure of an embodiment 3 of the equalizer circuit. In the embodiments 1 and 2, an example comprising the adjustable transversal filter with one delay step is disclosed; however, the embodiment 3 is a structural example of a case wherein the delay steps are over 2 steps (3 steps). The input signal I is delayed respectively at delay lines 250, 251, 252, and signals D1, D2, D3 are output. When a negative signal is required according to the characteristic of a preferable filter, a + signal and − signal of the differential signal are interchanged.

Adder circuits 253, 254, 255 consist of three blocks with the same structure. As for each block function, each input signal is multiplied by respective coefficients a1˜d1 by multipliers (attenuators) 260˜263, and added by an adder 264. As for an actual circuit, the signal which becomes a preferable filter characteristic corresponding to a specified cable length is synthesized and output by the resistance network.

Three variable gain amps 256˜258 correspond to the variable gain amps 116, 117 of the embodiment 1, and respective gains are relatively controlled so as to become a preferable output characteristic. An adder 259 adds output signals of all the variable gain amps, synthesizes them, and outputs them. Although the embodiment 3 is for a single end signal, a circuit for a differential signal can be obtained by making the circuit in FIG. 13 a differential structure, at which time, the variable gain amps 256˜258 with a differential structure are used.

According to the above-mentioned structure, the equalizer circuit of the invention is not required to have accurate control or large dynamic range for the gains in the variable gain amps, so that an equalizer circuit (transversal filter), which can process a signal with a transmission band over a few hundreds MHz can be easily obtained by a currently-available element or manufacturing technique.

Also, for the equalizer circuit of the invention, the following modified example can be considered. In the embodiment, signals from + input and − input are used for the circuits in FIGS. 8, 10, 12; however, an in-phase component of noise generated in a + input side and − input side can be eliminated by inserting the common-mode choke transformer into output ends of the amps 110, 111. Herewith, the noise of the equalizer circuit can be reduced. Also, in the embodiment, the fundamental form with one delay step for the transversal filter is disclosed; however, this one step fundamental form may be cascaded with a plurality of circuits according to the necessary characteristic for the equalizer circuit.

### Hybrid Circuit

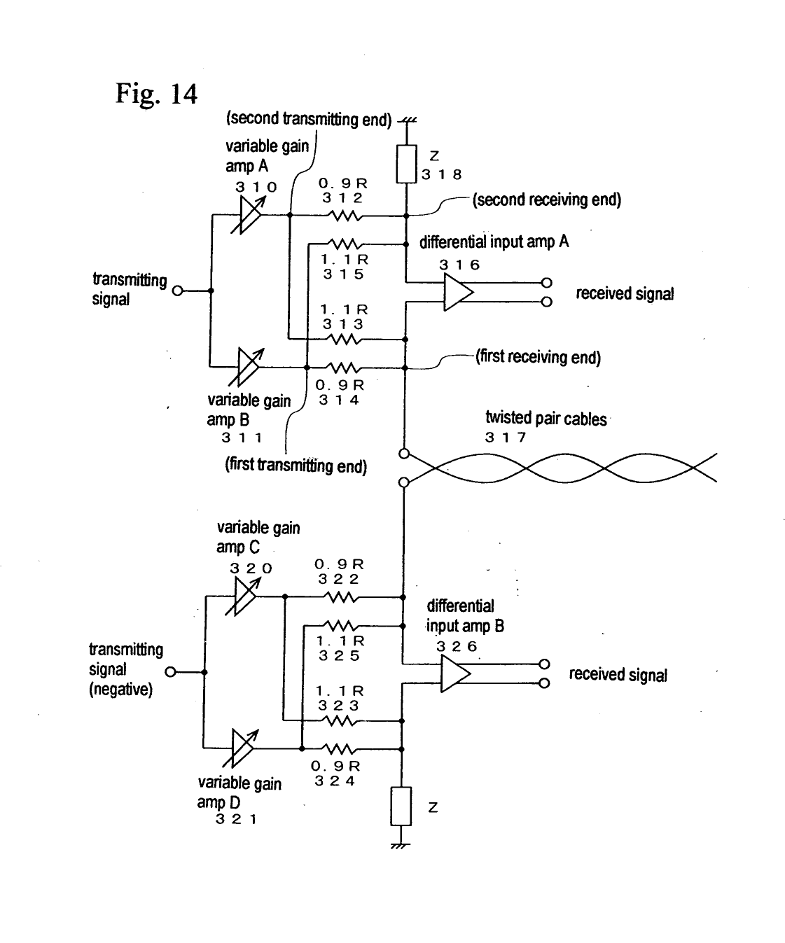

Next, the hybrid circuit 20 will be explained in details. FIG. 14 is a block diagram showing the hybrid circuit of the invention when twisted pair cables are used. Twisted pair cables 317 which are now widely used as a LAN cable have approximately 100Ω±10% of the characteristic impedance. In the hybrid circuit of the invention, the respective lines of the twisted pair cables are respectively terminated by two hybrid circuits with 50 Ω of the input impedance respectively.

In the circuits in FIG. 14, upper and lower circuits connected to respective lines of the cables 317 have the same structure. Therefore, only the upper circuit will be explained. A + output signal (− output signal) of differential output of a transmitting signal is input into the upper side (lower side) circuit. The input signal is input into two variable gain amps A310, B311. In the variable gain amps A310, B311, relative gains are adjusted so that, for example, transmitting signal power during received signal output becomes the minimum by the heretofore known means. Incidentally, one of the variable gain amps A310, B311 may be a fixity gain, and only the other may be adjusted.

Outputs (second transmitting ends) of the variable gain amp A310 are connected to the respective input terminals (first and second receiving ends) of a differential input amp A316 through the two respective resistances (0.9 R) 312 and (1.1 R) 313. Also, the outputs (first transmitting ends) of the variable gain amp B311 are connected to the respective input terminals of the differential input amp A316 through the two respective resistances (1.1 R) 315 and (0.9 R) 314. One line of the twisted pair cables 317 is connected to one of the input terminals (first receiving ends) of the differential input amp A316. The differential input amp A316 outputs a differential output signal according to a power voltage difference between the two differential input terminals (first and second receiving ends) as a received signal.

The ratio of the resistance values of the resistances 312, 313, and the ratio of the resistance values of the resistances 314, 315 are selected as 0.9 versus 1.1 respectively. Also, respective resistance values are selected in such a way that the input impedance viewed from the connection point of the twisted pair cables 317 also becomes 50 Ω.

For example, when output impedances of the variable gain amps A310, B311 are 50 Ω, and the impedance between the input terminals of the differential input amp A316 is 100 Ω, the impedance viewed from the cable connecting end (first receiving end) becomes approximately 50 Ω by making the resistances 312, 314 equal to 91 Ω, and making the resistances 313 and 315 equal to 110 Ω.

The impedance equivalent to the transmission channel is half the value of the characteristic impedance in the case of a balance cable, and equal to the characteristic impedance in the case of the coaxial cable. Impedance Z318 is a circuit including the same impedance (impedance equivalent to the transmission channel) as half the value of a standard characteristic impedance of the twisted pair cables 317. For example, the circuit may be a parallel circuit of the resistance and condenser. The condenser is attributed to floating capacitance of the cable, connector, wiring, and so on.

When the impedance of the twisted pair cables 317 is equal to two times the size of the impedance of this Z318, i.e. the impedance equivalent to the transmission channel is equal to the impedance of Z318, if the gains of two variable gain amps A310, B311 are made equal, the transmitting signals at the receiving ends become in-phase and the same level, and are cancelled. However, since the characteristic impedances of the cables are varied, transmitting signal levels at the receiving ends do not become the same. For example, when the characteristic impedance of the cables 317 is small, since the transmitting signal level at the first receiving end on a cable side deteriorates, the transmitting signal level at the first receiving end on the cable side can be elevated and balanced by making the gain of the variable gain amp B311 larger than the variable gain amp A310.

Noise components generated inside the respective amplifiers A310, B311 are inevitably output only for the imbalance part between the resistances 312, 314 and resistances 313, 315 without being cancelled at the receiving ends. However, this noise power is substantially decreased compared to the case without the resistances 313, 315.

Also, if the imbalance between the resistances 312, 314 and resistances 313, 315 is reduced, the noise component decreases for that reduced size. However, the adjustable range of the impedance becomes correspondingly narrower. Therefore, the ratio between the resistances 312, 314 and resistances 313, 315 is made close to 1 versus 1, as much as possible within the range to assure the adjustable range covering the variation of the characteristics of the LAN cable that is now widely used. If the ratio is 0.9 versus 1.1, ±20% adjustment can be possible. Since the embodiment does not use a transformer or choke coil, the embodiment can be the IC.

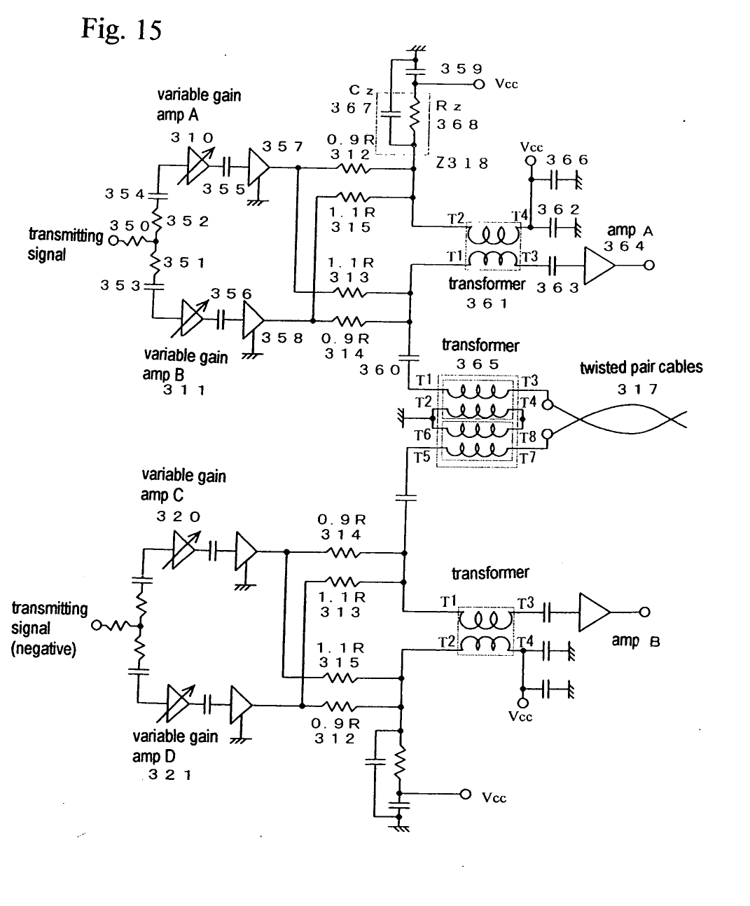

FIG. 15 is a circuit diagram showing a circuit example of the embodiment 1 of the hybrid circuit. Since the upper side circuit and lower side circuit are the same, only the upper side circuit will be explained. A (+) transmitting signal is input into two variable gain amps A310, B311 through resistances 350, 351, 352 for signal distribution and impedance matching, and direct-current cut condensers 353, 354. Moreover, the outputs of the amps A310, B311 are input into monolithic amp ICs 357, 358 of two fixity gains through direct-current cut condensers 355, 356.

For the variable gain amplifiers A310, B311, for example, the AD8370 by ANALOG DEVICES (registered trademark) can be used. This IC can digitally control gains from the outside. Also, the μPC2712TB by NEC (registered trademark) can be used. Since this IC can adjust the gain by changing power supply voltage, a power supply circuit able to control power voltage is required in order to adjust the gain.

For the monolithic amp ICs 357, 358, for example, the ERA-4 by Mini-Circuits (registered trademark) can be used. Since this IC has an output impedance of 50 Ω and supplies power through the output end, the power in the embodiment is supplied to respective ICs 357, 358 through the following transformer 361 and the resistances 312, 315.

Values of the resistances 312, 314 and 313, 315 are respectively, for example, 91 Ω and 110 Ω. Resistance Rz368, comprising the impedance Z318, and a condenser CZ367 are selected so as to be equivalent to half the value of the standard characteristic impedance of the twisted pair cables. Condensers 359, 360, 362, 363, 366 are direct-current cut condensers, and are equivalent to a condenser whose both ends are shorted to alternating current. Also, although Vcc, which is supplied to the Rz368 is not required, the Rz368 is required to be cut by direct current. A solid printed wiring pattern of the Vcc is provided for basal plate manufacturing, and the Rz368 is grounded in the high frequency wave, so that the Rz368 is connected to the Vcc.

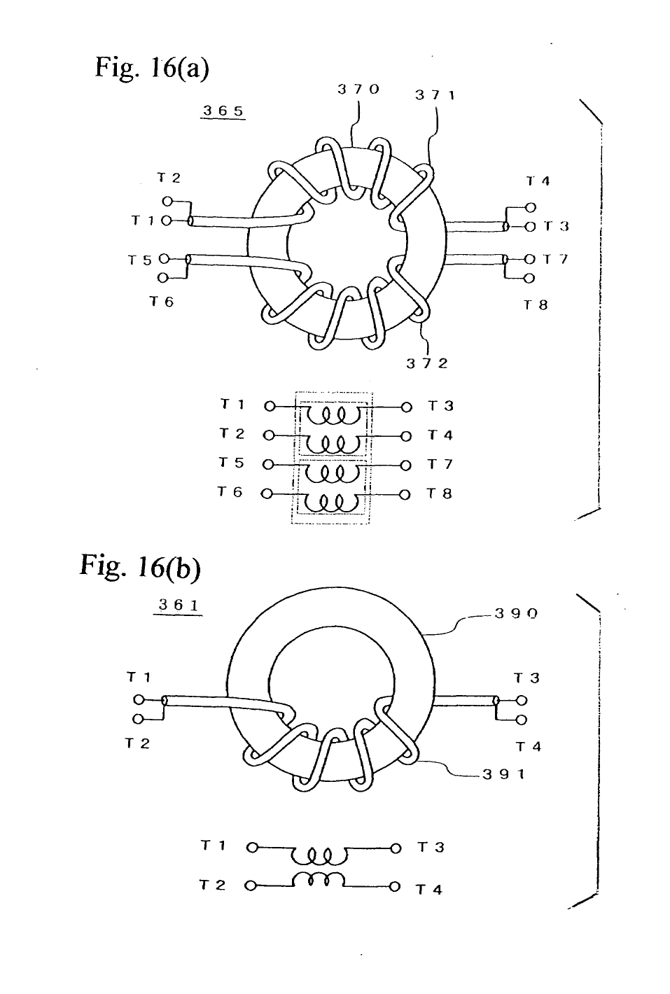

A transformer 365 includes the following structure, and blocks common-mode noise. FIGS. 16(a), 16(b) are a plan view and a diagram of a connection showing the structure of the transformer used in the embodiment of the invention. FIG. 16(a) shows the structure of the transformer 365 for the twisted pair cables. In the transformer 365, two thin coaxial cables 371, 372 are twisted in a toroidal core 370 consisting of a magnetic body in the same direction. A core wire and envelope conductor of each coaxial cable are coils respectively. By inserting the transformer with the above-mentioned structure between input and output ends of the hybrid circuit and cable, the impedance matching can be obtained relative to the differential signal transmitted through each cable line. Meanwhile, the in-phase common-mode noise due to electromagnetic induction and so on can be blocked. Also, by using the coaxial cable wherein the characteristic impedance is well-known and accurate as a winding line, the characteristic impedance between the lines can be precisely set.

For an input amplifier, as shown in FIG. 14, the differential input amp 316 may be used; however, in the circuit of the embodiment in FIG. 15, instead of the differential input amp A316 in FIG. 14, the transformer 361 and an amp A364 with a single end are used. FIG. 16(b) shows the structure of the transformer 361. As in the case of the above-mentioned transformer 365, in the transformer 361, a thin coaxial cable 391 is also twisted in a toroidal core 390. The transformer 361 can also obtain the impedance matching for the differential signal (received signal), and meanwhile, can block the common-mode noise (transmitting signal, noise generated inside the amp) Incidentally, for the amp A364, the above-mentioned ERA-4 can be used. According to the above-mentioned structure, a hybrid circuit for low noise twisted pair cables which can be used up to a high frequency can be achieved.

### EMBODIMENT 2 OF HYBRID CIRCUIT

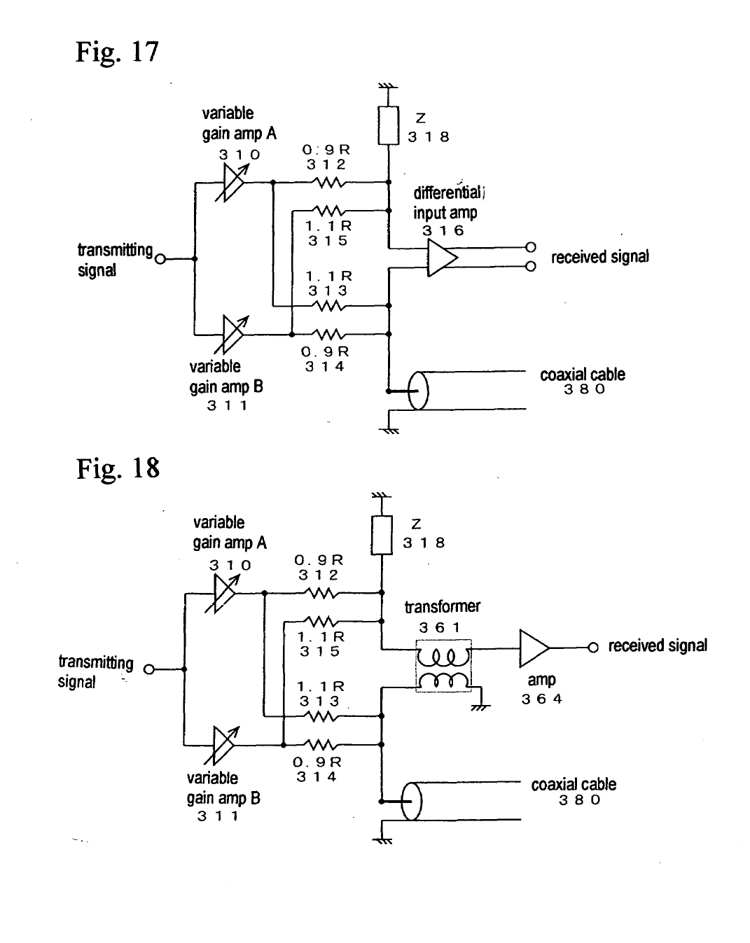

FIG. 17 is a block diagram showing the embodiment 2 of the hybrid circuit of the invention when the coaxial cable is used. The characteristic impedance of a coaxial cable 380 is, for example, 50 Ω, and for example, one of the hybrid circuits for the twisted pair cables shown in FIG. 14 can be used as the hybrid circuit for the coaxial cables. Element, function, and operation are also the same as the above-mentioned circuit. Since the coaxial cables have smaller attenuation than the twisted pair cables do, longer distance transmission can be possible.

FIG. 18 is a block diagram showing a modified example of the circuit in FIG. 17. In this circuit, as in the case of the circuit shown in FIG. 15, instead of the differential input amp 316, the transformer 361 and the amp 364 with the single end are used.

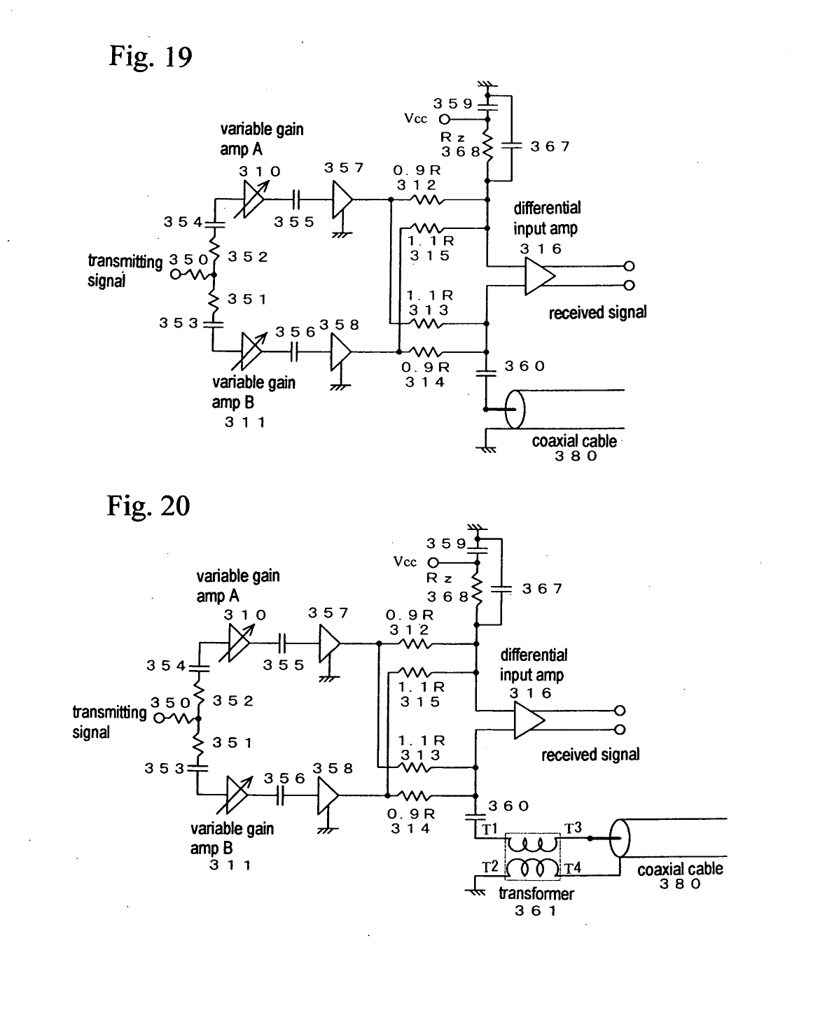

FIG. 19 is a circuit diagram showing the circuit example of the embodiment 2. This circuit example is the same as one of the circuits of the embodiment 1 of the hybrid circuit shown in FIG. 15 except for using the differential input amp 316 as the input amp. In this embodiment, power is supplied to respective ICs 357, 358 through the resistances 368, and 312, 315. This structure can be the IC.

FIG. 20 is a circuit diagram showing a modified example of the circuit example of the embodiment 2 of the hybrid circuit. This circuit example is an example wherein the transformer 361 is inserted between the coaxial cable 380 and input and output ends of the hybrid circuit. The transformer 361 has the structure shown in FIG. 16(b). This also allows the impedance matching to be obtained, and meanwhile, allows the common mode noise to be blocked. This embodiment can also be IC except for the transformer.

According to the above-mentioned structure, in the hybrid circuit of the invention, since the noise generated inside the respective variable gain amps is also supplied to the two receiving ends respectively, the noise is nearly cancelled at the receiving ends, and a low-noise hybrid circuit can be obtained. Also, the hybrid circuit can be structured only by the element which is now available and usable up to a high frequency without using an adjustable passive element and so on, so that a hybrid circuit able to be used up to a high frequency can be obtained. Moreover, the circuit can be structured without using the transformer or coil, and the circuit structure can be the IC.

Hereinbefore, the embodiment of the hybrid circuit is disclosed; however, the following modified example can be also considered. In the embodiment, for example, in the structure in FIG. 14, an example with four resistances 312˜315 is disclosed. However, even in a structure without the resistances 313, 315 (without an electric connection), the transmitting signal component in the received signal can be cancelled. Therefore, in application wherein a dynamic range (S/N ratio) is allowed to not be very large, even the structure without the resistances 313, 315 can be available.

In the structure in FIG. 14, when the variable gain amps are structured by the differential circuits, variable gain amps A310, D321, and variable gain amps B311, C320 may be structured by a unified circuit with respective equal characteristics. Also, in the structure in FIG. 15, when the variable gain amps are structured by the differential circuits, the variable gain amps A310, D321, and variable gain amps B311, C320, additionally, variable gain amps A364, B326 may be structured by a unified circuit with respective equal characteristics.

### Waveform Adjustment System

Next, a waveform adjustment system applicable to the present invention will be explained. First, in the waveform adjustment system of the invention, instead of the THP precoder 12 in FIG. 1, the following spread spectrum (SS) encoder is used. In the SS encoder, an operation of Yn=Mod (Xn−Yn−1) is carried out. Here, the reference alphabets Yn represent an output signal; Mod represent a modulo arithmetic; Xn represent an input signal; and Yn−1 represent an output signal before 1 clock. When this is additionally generalized, the following formula is indicated.

Yn=Mod (Xn−a1Yn−1−a2Yn−2−a3Yn−3

Here, a coefficient “an” is required to be an integer number.

In the receiving side, instead of the THP decoder 34, the following SS decoder is used. On a SS decoder side, the following processing is conducted. More specifically, Yn=Mod (Xn+Xn−1). When this is generalized, Yn=Mod (a0Xn−a1Xn−1−a2Xn−2−a3Xn−3 . . . ), and a0=1.

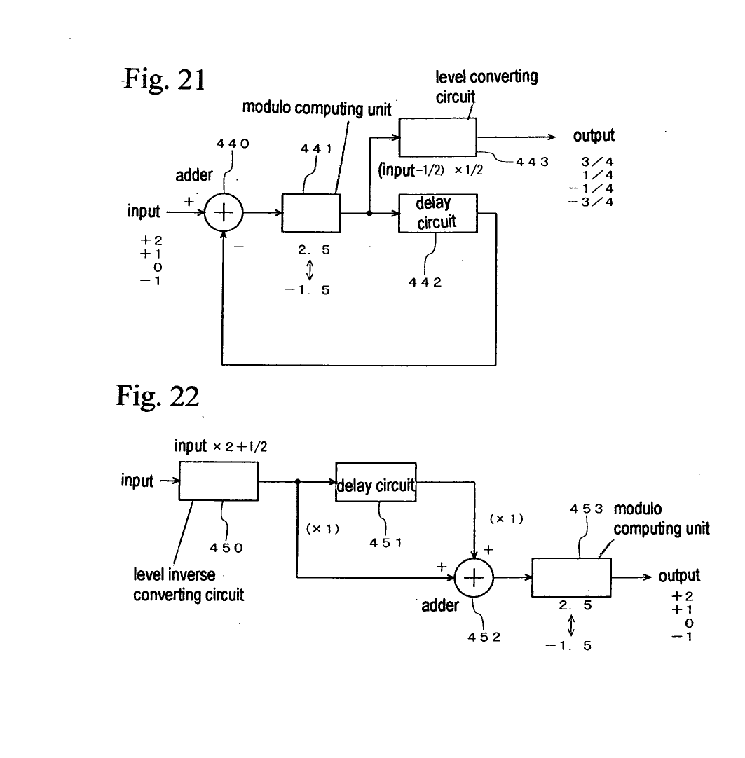

FIG. 21 is a block diagram showing the structure of the SS encoder of the present invention. Incidentally, in the waveform adjustment system, the code converter 11 divides the transmitting data into a bit sequence of a predetermined bit number, and outputs one of multiple signal levels (voltage level) in response to the value of the bit sequence. For example, the code converter 11 divides the transmitting data into every 2 bits, and outputs any of four values of 2, 1, 0, −1 according to the contents of the respective bit sequences.

An adder 440 which is a subtraction means subtracts the output signal of a delay circuit 442 from the input signal. A modulo computing unit 441 performs the modulo arithmetic so that the output signal is fitted into a predetermined width.

In the embodiment, if the input value of the modulo computing unit 441 is within the range of −1.5˜+2.5, the input value is output as it is. However, if the input value is beyond the range, the signal value is converted within the range of −1.5˜+2.5 by adding or subtracting the value wherein the integer number of the width of modulo arithmetic=4 is multiplied to the input value. For example, if the input value is 3, 4 is subtracted, so that the output value becomes −1.

The delay circuit 442 is a memory circuit for allowing the signal to delay only for one signal section (for one clock). A level converting circuit 443 converts and shifts the level of the input signal. In the embodiment, arithmetic which becomes an output signal=(input signal−½)×½ is operated. As a result, the level converting circuit 43 outputs any of 4 values of ¾, ¼, −¼, −¾.

FIG. 22 is a block diagram showing the structure of the SS decoder which is used instead of the THP decoder 34. The SS decoder consists of a level inverse converting circuit 450, delay circuit 451, adder 452, and modulo computing unit 453. The level inverse converting circuit 450 is the circuit inversely converting the converting function of the level converting circuit 443 inside the SS encoder. In the embodiment, an arithmetic operation which becomes an output signal=(input signal×2)+½ is carried out. As a result, when any of 4 values of ¾, ¼, −¼, −¾ is input, any of 4 values of 2, 1, 0, −1 is output from the level converting circuit 443.

The delay circuit 451 is the memory circuit for allowing the output signal of the level inverse converting circuit 450 to delay only for one single section (for one clock). The adder 452 adds the output signal of the level inverse converging circuit 450 and the output signal of the delay circuit 451. The modulo computing unit 453 has the same structure as the modulo computing unit 441 of the SS encoder. Ideally, any of 4 values of 2, 1, 0, −1 is output from the modulo computing unit 453.

The slicer (determination circuit) 35, of FIG. 1, is the circuit determining within which area the signal with multiple values exists. For example, if the input signal level is below −½, the slicer 35 outputs [0001]; if the input signal level is over −½ and below ½, the slicer 35 outputs [0011]; if the input signal level is over ½ and below 3/2, the slicer 35 outputs [0111]; and if the input signal level is over 3/2, the slicer 35 outputs [1111]. The code inverter 36 inversely transforms the output of the above-mentioned slicer to the original bit information (for example, 2 bits information).

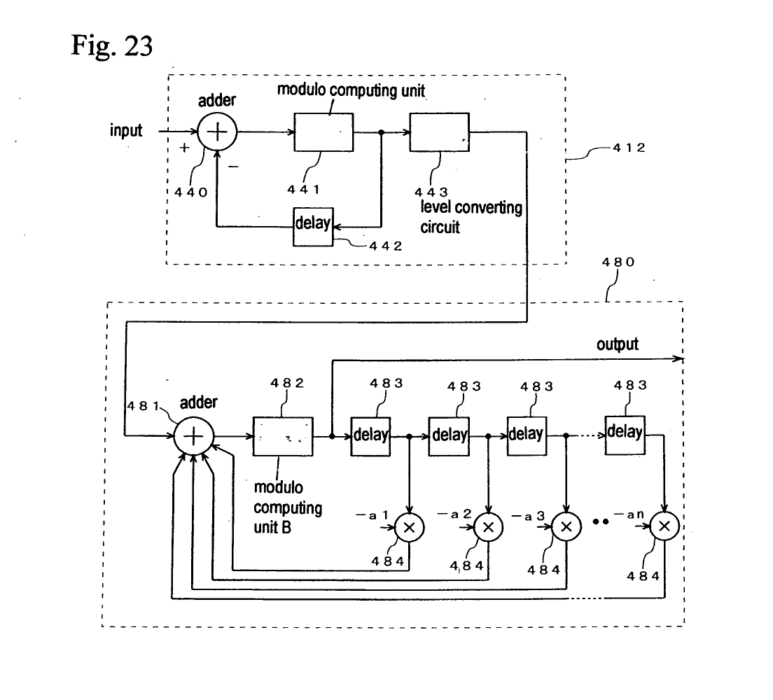

FIG. 23 is a block diagram showing the structure of the SSTHP encoder which is the second embodiment. The embodiment 2 is a combination of the waveform adjustment system of the first embodiment and the THP system. The SSTHP encoder consists of 2 blocks, and the structure of the front step part is the same as an SS encoder 412 of the first embodiment. A THP precoder part 480 of the back step comprises the adder, modulo computing unit, and FIR filter functionally; however, in the structure in FIG. 23, an adder 481 combines the adder inside the FIR filter.

The adder 481 subtracts the output of the FIR filter from the input signal and outputs it. A modulo computing unit B482 functions in such a way that the output signal is fitted into the predetermined width W. If the input signal is run off the range of the width W, the amount wherein the width W is multiplied by an integer number is subtracted, and then the input signal is fitted into the width W. However, the modulo computing unit B482 has a different characteristic from the above-mentioned modulo computing unit 441. For example, the width W is in the range of −1˜+1. Therefore, by making an upper level bit of the input signal 0, a modulo arithmetic result can be obtained.

A delay circuit 483 which is a component part of the FIR filter is the shift register for allowing the signal to delay for only one signal section (for one block), and a multiplier 484 multiplies the coefficient (−al˜−an) of the impulse response of the transmission channel which was obtained by the training processing. The number of steps of the FIR filter is, for example, 16˜64. The output of the SSTHP encoder is converted to an analog signal by the DAC 15, amplified, and transmitted through the hybrid circuit 20.

The SSTHP decoder has the same structure as the SS decoder shown in FIG. 22. In the case of the usual THP system, a modulo computing unit for THP is required on the receiving end; however, there is the modulo computing unit 453 inside the SS decoder, and this modulo computing unit 453 combines the function of the modulo computing unit for THP.

In a conventional pre-emphasis system, since the level of a high-pass component in a transmitting end increases, if the LAN cable wherein the multiple twisted pair cables are housed is used, crosstalk inevitably increases. The waveform adjustment system of the invention can control sensitivity relative to the high-frequency component of the signal, and decrease an effect of the crosstalk, so that SNR improves. Especially, when a THP precoder means is used, a signal spectrum on the transmitting side is maintained evenly. At the same time, since effective sensitivity of the high-frequency area of the receiving part can be controlled, the effect of the crosstalk decreases, and the SNR significantly improves.

Also, in the waveform adjustment system of the invention, the following modified example can be considered. A direct-current drift component is generated according to the moving average value between a few symbols and dozens of symbols of the transmitting signal voltage with multiple values. By eliminating the direct-current drift component, quality of transmission can be improved. Hereinafter, a means for eliminating an adverse effect of the direct-current drift component will be disclosed.

In the code converter 11, when a transmitting signal is generated, a corresponding relationship between a bit of data called a symbol mapping and a signal spot (signal level) is defined beforehand. However, in many cases, there are surplus signal spots which do not have bit quota. By using the surplus signal spots without the bit quota, the direct-current drift component can be decreased. More specifically, the bit of the surplus signal spots may be set in such a way that the moving average value of the transmitting signal voltage is close to 0. This bit setting processing can be achieved quite easily in a digital circuit.

Herewith, since the bit of the surplus signal spots of the code converter 11 is set so that the moving average value of the transmitting signal voltage becomes close to 0, the effect of the direct-current drift component can be avoided, and quality of communication can be improved. Moreover, since the direct current component of the transmitting signal itself is decreased, maximal value of the signal amplitude at the receiving spot decreases, and low-frequency characteristic demand of the transmission channel is also reduced. As a result, since a much less dynamic range is required on the receiving side, the number of bits of the AD converter can be reduced.

What is claimed is:

1. Transmission equipment comprising:
a Tomlinson Harashima Precoding (THP) precoding means on a transmitting side; and
an equalizer means for analog processing on a receiving side.

2. Transmission equipment according to claim 1, wherein a Finite Impulse Response (FIR) filter means for eliminating rounding of a waveform is provided on the receiving side.

3. Transmission equipment according to claim 1, wherein said equalizer means comprises:
a delay means for delaying one signal of a differential signal;
an adder means for inputting the other signal of the differential signal and an output signal of said delay means, and outputting multiple adding signals, wherein two signals are added in varying proportions respectively;
multiple variable gain amplification means for amplifying said multiple adding signals respectively; and
an output synthetic means for adding output signals of said multiple variable gain amplification means.

4. Transmission equipment according to claim 3, wherein said adder means comprises multiple resistance means connected in series.

5. Transmission equipment according to claim 1, comprising:
a reception amplification means for outputting a signal between a first receiving end, wherein a transmission line is connected, and a second receiving end, wherein an impedance circuit equivalent to a transmission channel is connected;
a first variable gain amp means for driving a first transmitting end, wherein the first variable gain amp means includes an input that receives a transmitting signal, for driving ;
a second variable gain amp means for driving a second transmitting end, wherein the second variable gain amp means includes an input that receives the transmitting signal;
a first resistance means for connecting said first receiving end and said first transmitting end;
a second resistance means for connecting said first receiving end and said second transmitting end;
a third resistance means for connecting said second receiving end and said first transmitting end;
a fourth resistance means for connecting said second receiving end and said second transmitting end; and
a hybrid circuit, wherein a resistance value of said first resistance means is smaller than a resistance value of said third resistance means, and a resistance value of said fourth resistance means is smaller than a resistance value of said second resistance means.

6. A transmission method comprising:
a step for performing a THP preceding processing on the transmitting side; and
a step for performing an analog equalizer processing on the receiving side.
